(19) United States
(12) Patent Application Publication
(10) Pub. No.: US 2025/0080919 A1
(43) Pub. Date: Mar. 6, 2025

(54) MEMS SOUND TRANSDUCER AND METHOD FOR PRODUCING SAME

(71) Applicant: USOUND GMBH, Graz (AT)

(72) Inventors: Andrea Rusconi Clerici Beltrami, Wien (AT); Ferruccio Bottoni, Graz (AT); Christian Novotny, Wien (AT); Samu Bence Horváth, Wien (AT)

(21) Appl. No.: 18/816,124

(22) Filed: Aug. 27, 2024

(30) Foreign Application Priority Data
Aug. 29, 2023 (DE) 10 2023 123 231.2
Sep. 19, 2023 (DE) 10 2023 125 392.1

(51) Int. Cl. H04R 17/02

(52) U.S. Cl. CPC H04R 17/02; H04R 2201/003

(57) ABSTRACT

In one aspect, a MEMS sound transducer for generating and/or detecting sound waves in the audible wavelength spectrum and/or in the ultrasonic range includes a carrier and at least one piezoelectric element. The at least one piezoelectric element is arranged on the carrier and is deflectable in the direction of a stroke axis. The at least one piezoelectric element has at least one piezoelectric layer and at least one structural layer, wherein electrical signals and deflections of the at least one piezoelectric element are convertible into each other using the at least one piezoelectric layer. Additionally, the at least one piezoelectric layer is made of scandium aluminum nitride.

### CROSS-REFERENCE TO RELATED APPLICATIONS

The present application is based upon and claims the right of priority to German Patent Application No. 10 2023 123 231.2, filed Aug. 29, 2023, and German Patent Application No. 10 2023 125 392.1, filed Sep. 19, 2023, the disclosures of which are hereby incorporated by reference herein in their entirety for all purposes.

### FIELD OF THE INVENTION

The present subject matter relates to a MEMS sound transducer, in particular for generating and/or detecting sound waves in the audible wavelength spectrum and/or in the ultrasonic range, having a carrier and having at least one piezoelectric element, which is arranged on the carrier, is deflectable in the direction of a stroke axis, and has at least one piezoelectric layer and at least one structural layer, wherein, by means of the at least one piezoelectric layer, electrical signals and deflections of the piezoelectric element can be converted into one another.

### BACKGROUND OF THE INVENTION

Piezoelectric elements which have piezoelectric layers made of PZT are known from the state of the art.

Generally, a need exists for high-performance MEMS sound transducers.

### SUMMARY OF THE INVENTION

In various aspects, the present subject matter is directed to a MEMS sound transducer and a method for producing same having the features described and claimed herein.

In one aspect, the present subject matter relates to a MEMS sound transducer, in particular for generating and/or detecting sound waves in the audible wavelength range and/or in the ultrasonic range. The MEMS sound transducer can therefore be operated as a loudspeaker and/or as a microphone.

The MEMS sound transducer includes a carrier.

Moreover, the MEMS sound transducer has at least one piezoelectric element, which is arranged on the carrier and is deflectable in the direction of a stroke axis.

In addition, the MEMS sound transducer has at least one piezoelectric layer and at least one structural layer. By means of the at least one piezoelectric layer, electrical signals and deflections of the piezoelectric element can be converted into one another.

Furthermore, the at least one piezoelectric layer is made of scandium aluminum nitride. Such piezoelectric layers are highly robust, which is due, in particular, to the scandium content, which can preferably be between 10% and 40%.

According to one advantageous enhanced embodiment of the invention, it is useful when the at least one structural layer is made of a polymer. The polymer can be a polyamide in one embodiment. By means of the at least one structural layer made of polymer, greater deflections of the piezoelectric element can be achieved. Additionally or alternatively, a length of the piezoelectric element can also be shortened, in which case the deflections can be held at least constant.

It is advantageous when the piezoelectric element has a compensation layer. By means of the compensation layer, a mechanical tension of the structural layer made of the polymer can be adapted. Due to the structural layer being made of the polymer, the structural layer tends to contract. Due to the properties during production and/or the properties of the polymer, the at least one structural layer can have an internal mechanical tension that tends to contract the structural layer. In an idle state, the piezoelectric element would bend upward, or in the direction of the structural layer. The mechanical tensions can be compensated for by means of the compensation layer. The compensation layer has a mechanical tension that counteracts, compensates for and/or equalizes the at least one structural layer. The compensation layer is therefore used to equalize mechanical tensions of the at least one structural layer. Additionally or alternatively, the compensation layer is used to flatten the at least one structural layer. The compensation layer holds the at least one structural layer in the flat orientation, thereby preventing the structural layer from contracting and thus deforming similarly to a rubber band due to impressed mechanical tensions. Additionally or alternatively, the compensation layer is used to prevent the at least one structural layer made of the polymer from contracting. The compensation layer counteracts the mechanical tension of the at least one structural layer made of polymer and/or is stronger and/or more robust than the mechanical tension of the at least one structural layer. Consequently, the at least one structural layer is prevented from contracting. The force applied by the at least one structural layer made of polymer and the force applied by the compensation layer oppose each other and/or advantageously equalize one another and/or cancel each other out. This prevents the structural layer from contracting. The compensation layer does not prevent the piezoelectric element from deflecting, however. The mechanical tension of the compensation layer is adjusted such that it prevents, or equalizes, or compensates for, the rubber-like contraction of the structural layer. Moreover, the compensation layer can be used to ensure that the piezoelectric element is tension-free when in an idle position.

Moreover, by means of the compensation layer, a neutral layer, or a neutral plane, of the piezoelectric element can be positioned within the piezoelectric element. The piezoelectric element is a cantilever arm and, when the piezoelectric element is deflected, a compressive stress and a tensile stress build up therein. The regions of the compressive stress and the tensile stress depend on whether the piezoelectric element deflects upward or downward. The compressive stresses are formed on the side, in the direction of which the piezoelectric deflects. The tensile stresses build up on the opposite side. This is a general principle of the science of the strength of materials. In a plane in the piezoelectric element, specifically in the neutral plane, or in the neutral layer, the tensile stress and the compressive stress cancel each other out and, therefore, no tension occurs there. The deflection properties of the piezoelectric element depend, however, on the location at which this neutral plane, or neutral layer, is located in the piezoelectric element. The position of the neutral plane, or of the neutral layer, can be adapted by changing mechanical properties of the compensation layer. For example, the compensation layer can be made thicker or thinner in order to shift the neutral plane, or the neutral layer. This shift, or positioning, of the neutral plane, or of the neutral layer, takes place parallel to the stroke axis. The neutral plane, or neutral layer, can be shifted parallel to the stroke axis as a result.

It is advantageous when the piezoelectric layer is arranged between the carrier and the structural layer in the direction of the stroke axis.

It is useful when the structural layer is arranged between the piezoelectric layer and the compensation layer.

It is advantageous when the compensation layer is made of a metal, in particular gold, and/or silicon dioxide, in particular TEOS. As a result, the compensation layer can be advantageously formed.

It is advantageous when the piezoelectric element has a length in the longitudinal direction thereof, in particular from the carrier to a free end of the piezoelectric element, between 0.5 mm and 2 mm.

It is useful when the compensation layer extends in a longitudinal direction of the piezoelectric element to the carrier and/or to the free end of the piezoelectric element.

It is advantageous when the at least one piezoelectric element has multiple, in particular between two and six, preferably four, piezoelectric layers.

An advantage results when the at least one piezoelectric element has at least one electrode layer. The electrical signals can be exchanged by means of the at least one electrode layer, which electrical signals result in the deflection of the piezoelectric element and/or are formed when the piezoelectric element is deflected.

It is advantageous when the at least one piezoelectric element has at least one insulation layer.

It is advantageous when the at least one piezoelectric element is formed from the multiple piezoelectric layers and the electrode layers in a sandwich-like manner.

An advantage results when the MEMS sound transducer has a coupling element, with which the at least one piezoelectric element can be coupled to a diaphragm.

An improvement results when the piezoelectric element and the coupling element are coupled to each other by means of at least one spring element, the at least one spring element preferably being arranged between the structural layer and the coupling element in the longitudinal direction of the piezoelectric element.

It is advantageous when the spring element is formed, preferably exclusively, by the structural layer and/or the polymer. As a result, the spring element can be easily formed. Additionally or alternatively, the spring element has the mechanical properties of the polymer.

It is useful when the piezoelectric element and the coupling element have the same layered construction.

An advantage results when the compensation layer is between 0.2 μm and 4 μm thick. Furthermore, the compensation layer can be between 0.5 μm and 3 μm thick. Moreover, the compensation layer can have a thickness between 0.6 μm and 2 μm. Alternatively, the compensation layer can be between 1 μm and 2 μm thick. As a result, the contraction of the structural layer can be prevented and/or compensated for by means of the compensation layer.

An improvement results when the structural layer is between 10 μm and 50 μm thick.

It is advantageous when the at least one piezoelectric element has at least one recess. By means of the recess, the mechanical properties of the piezoelectric element can be adapted. For example, as a result, tensions in the piezoelectric element can be reduced and/or the motion characteristics can be adapted. The at least one recess can be arranged in the at least one piezoelectric layer, in the at least one electrode layer, in the at least one insulation layer, in the at least one structural layer, and/or in the at least one compensation layer.

Moreover, it is advantageous when the structural layer made of the polymer has a modulus of elasticity between 2 GPa and 50 GPa, in particular between 2 GPa and 5 GPa, preferably between 3.5 GPa and 4 GPa.

An advantage results when the structural layer made of the polymer has a tensile strength between 70 MPa and 100 MPa, in particular between 85 MPa and 95 MPa.

Due to the aforementioned mechanical properties of the at least one structural layer, the deflections can be enlarged and/or the piezoelectric element can be shortened while the size of the deflection at least remains the same or the deflection enlarges.

Moreover, it is advantageous when the compensation layer has a state of mechanical tension that is as high as or at least minimally higher than the at least one structural layer. Additionally or alternatively, the compensation layer can have a higher durability than the structural layer. The state of mechanical tension of the compensation layer can counteract a state of mechanical tension of the at least one structural layer. As a result, the compensation layer can hold the at least one structural layer in the flat orientation. As a result, the compensation layer can resist the structural layer, or prevent the structural layer from contracting due to the mechanical tension. When multiple structural layers are present, the compensation layer has a state of mechanical tension that is equal to or higher than the structural layers in total. Additionally or alternatively, the compensation layer can also have a state of mechanical tension that counteracts the piezoelectric element, or causes the piezoelectric element to be tension-free when in a neutral position. The state of mechanical tension depends on multiple factors. The required state of mechanical tension of the compensation layer depends on the thickness of the structural layer, or the thicknesses of all structural layers, and a modulus of elasticity, the tensile strength, and/or the elasticity of the structural layer, or of the polymer. The polymer can have a rubber elasticity, due to which the structural layer tends to contract. The compensation layer has a mechanical state of tension such that it can counteract the contraction of the polymer. The force with which the polymer tends to contract depends on the thickness and the strength of the polymer, i.e., for example, on the strength of the rubber elasticity. The state of mechanical tension of the compensation layer also depends on the thickness and the modulus of elasticity, or the compressive strength, of the compensation layer.

The compensation layer has a state of mechanical tension that is equal to or greater than the structural layer or the totality of all structural layers and/or the piezoelectric layers. This equal or greater state of mechanical tension enables the compensation layer to hold the structural layer(s) and/or the piezoelectric layers in their flat position and to provide stability thereto. The compensation layer is used to counteract the tendency of the structural layer to contract due to its elastic properties.

It is advantageous when the state of mechanical tension of the compensation layer counteracts, compensates for, and/or equalizes the state of mechanical tension of the at least one structural layer and/or of the at least one piezoelectric layer. For example, the mechanical tension of the compensation layer can be between 50 MPa and 1000 MPa. Furthermore, the mechanical tension of the compensation layer can be between 100 MPa and 300 MPa. Moreover, the mechanical tension of the compensation layer can be 240 MPa.

The required mechanical tension of the compensation layer can be determined by various factors. These include the thickness of the structural layer(s), the modulus of elasticity (elasticity modulus), the tensile strength, and the elasticity of the structural layer, or of the polymer. A thicker structural layer requires a correspondingly more robust compensation layer and/or a compensation layer having a greater mechanical tension in order to equalize the elastic forces. The compensation layer therefore advantageously has the ability to counteract this contraction.

The force with which the polymer tends to contract depends on multiple factors. These include the thickness of the polymer and the strength of the elastic property of the polymer. A thicker polymer generates a stronger mechanical tension. The mechanical tension of the compensation layer is also determined by its own thickness and its modulus of elasticity. A thicker compensation layer having a higher modulus of elasticity can counteract a stronger mechanical tension of the polymer.

The compensation layer is advantageously strong enough to equalize the elastic restoring forces of the structural layer and, therefore, maintain the stability of the entire structure.

Moreover, it is advantageous when the compensation layer has a stiffening structure. For example, the compensation layer can have a strip-shaped stiffening structure or can be designed in this manner. As a result, the mechanical tension necessary to prevent the structural layer from contracting can be achieved. In addition, material can therefore be reduced and/or placed anywhere.

It is useful when the structural layer made of polymer is designed such that an elongation of between 3% and 10% can be achieved.

The present subject matter also relates to a method for producing a MEMS sound transducer, in particular for generating and/or detecting sound waves in the audible wavelength range and/or in the ultrasonic range. The method for producing the MEMS sound transducer can be carried out such that the MEMS sound transducer is formed having at least one feature of the preceding description and/or the following description.

In the method, at least one piezoelectric element is formed on a carrier, the piezoelectric element having at least one piezoelectric layer and at least one structural layer coupled thereto.

In addition, a polymer can be arranged on the piezoelectric layer in order to form the at least one structural layer.

The at least one piezoelectric layer is made of scandium aluminum nitride.

It is also advantageous when the at least one piezoelectric element is formed having multiple, in particular between two and six, in particular four, piezoelectric layers.

It is useful when the at least one piezoelectric element is formed of the multiple piezoelectric layers and at least one electrode layer in a sandwich-like manner.

The multiple piezoelectric layers and multiple electrode layers can be arranged alternatingly one above the other.

Moreover, it is advantageous when at least one insulation layer is included during the build-up of the at least one piezoelectric element.

It is useful when the structural layer made of the polymer is arranged on a side of the piezoelectric layer facing away from the carrier.

An improvement results when the structural layer made of the polymer is arranged on the at least one piezoelectric layer once the piezoelectric layer and/or a coupling element have/has been formed and/or once the carrier, the piezoelectric layer and/or the coupling element have/has been reworked, in particular by means of etching, in particular being separated from one another.

It is useful when the piezoelectric element and the coupling element are built up together in a layered construction, this preferably being carried out on the carrier.

It is advantageous when, once the piezoelectric element and the coupling element have been built up in a layered construction, these are separated from one another, at least in some sections, in particular by means of etching.

Moreover, it is advantageous when the at least one structural layer made of polymer is laminated onto the piezoelectric layer and/or the coupling element, in particular in the form of a, preferably self-adhesive, polymeric film.

An advantage results when two structural layers are formed, which are preferably arranged one above the other and/or which are made of the same polymer and/or a different polymer.

It is advantageous when the lamination of the structural layer made of the polymer is carried out at a temperature between 70° C. and 90° C.

It is useful when, after the lamination, a curing step of the polymer is carried out, this curing step preferably being carried out at a temperature between 150° C. and 200° C. and/or for a duration between 0.5 hours and 2 hours.

According to one advantageous enhanced embodiment of the present subject matter, it is useful when a compensation layer is arranged on the structural layer.

It is useful when the at least one structural layer made of the polymer is reworked.

### BRIEF DESCRIPTION OF THE FIGURES

Further advantages of the invention are described in the following exemplary embodiments, wherein:

FIG. 1 shows a schematic sectional view of a MEMS sound transducer having a piezoelectric element formed from at least one piezoelectric layer and at least one structural layer,

FIG. 2 shows a schematic sectional view of a MEMS sound transducer having two piezoelectric elements and one coupling element,

FIG. 3 shows a schematic sectional view of a MEMS sound transducer having two piezoelectric elements and two coupling elements,

FIG. 4 shows a schematic sectional view of a MEMS sound transducer with its layered construction, and

FIG. 5 shows a top view of a MEMS sound transducer.

### DETAILED DESCRIPTION

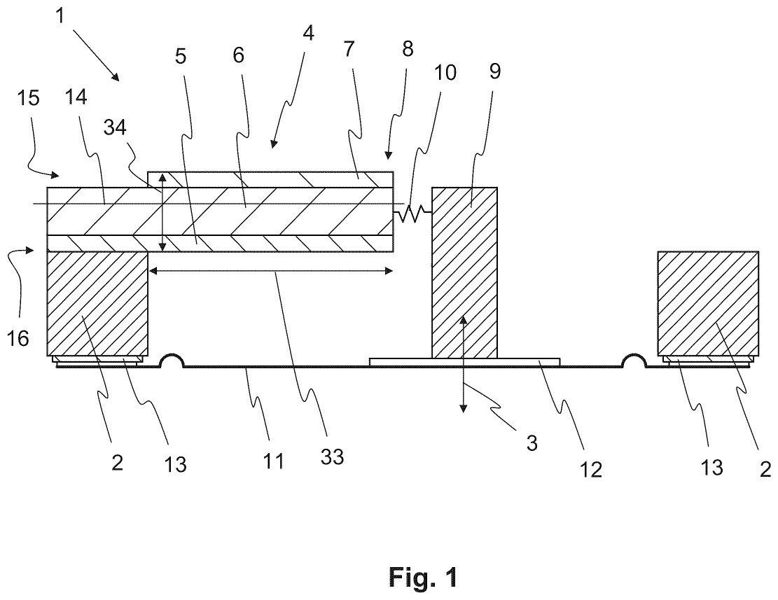

FIG. 1 shows a perspective view of a MEMS sound transducer 1. By means of the MEMS sound transducer 1, for example, sound waves in the audible wavelength spectrum can be generated, enabling the MEMS sound transducer 1 to be operated as a MEMS loudspeaker. Additionally or alternatively, by means of the MEMS sound transducer 1, sound waves in the audible wavelength spectrum can be detected, allowing the MEMS sound transducer 1 to be operated as a MEMS microphone. Furthermore, the MEMS sound transducer 1 can be arranged, for example, in a smartphone, in order to allow telephoning or listening to music. The MEMS sound transducer 1 can also be arranged, for example, in headphones.

A further area of application of the MEMS sound transducer 1 can also be that of generating and/or detecting sound waves in the ultrasonic range. The MEMS sound transducer 1 can be arranged, for example, in an ultrasonic sensor, for example, a distance sensor.

Furthermore, the MEMS sound transducer 1 has a carrier 2, which can form a framework of the MEMS sound transducer 1. The carrier 2 can include, for example, a semiconductor substrate, which can be produced in an etching process. The carrier 2 can be made, for example, of silicon and/or have the shape of a wafer. Two carriers 2 are shown in the present view. The carrier 2 can be in the form of a frame, however, so that the two elements of the carrier 2 shown in FIG. 1 can be contiguous in the sectional view shown in FIG. 1. For example, the carrier 2 can be rectangular as seen in a top view. The top view can be oriented, for example, in the direction of a stroke axis 3, which is explained below. The top view can be, for example, parallel to the axis 3. For example, at least one piezoelectric element 4 can face, at least in part, an interior of the carrier 2 when the carrier 2 is in the form, for example, of a frame.

Moreover, at least one piezoelectric element 4 is arranged on the carrier 2. The at least one piezoelectric element 4 can also be coupled to the carrier 2. The at least one piezoelectric element 4 can be deflected along the stroke axis 3 shown. In this process, the at least one piezoelectric element 4 can convert electrical signals into deflections, such that the MEMS sound transducer 1 is operated as a loudspeaker and the sound waves can be generated. Additionally or alternatively, by means of the at least one piezoelectric element 4, deflections can also be converted into electrical signals, such that the MEMS sound transducer 1 is operated as a microphone and the sound waves can be detected.

The at least one piezoelectric element 4 has a free end 8, which can deflect along the stroke axis 3.

The piezoelectric element 4 also includes least one piezoelectric layer 5. The at least one piezoelectric layer 5 is made of a piezoelectric material. The at least one piezoelectric layer 5 can convert electrical signals into deflections and/or deflections into electrical signals. The piezoelectric layer 5 is made of scandium aluminum nitride (ScAlN) in this case.

In addition, the piezoelectric element 4 has at least one structural layer 6. The structural layer 6 is coupled to the at least one piezoelectric layer 5. According to the present exemplary embodiment, the at least one structural layer 6 is arranged on a side of the at least one piezoelectric layer 5 facing away from the carrier 2. Additionally or alternatively, the at least one piezoelectric layer 5 is arranged between the carrier 2 and the at least one structural layer 6. The at least one piezoelectric layer 5 can be stabilized by means of the at least one structural layer 6. Furthermore, the at least one piezoelectric layer 5 can be prevented from breaking during deflection by means of the at least one structural layer 6. The at least one structural layer 6 can also act as a support layer for the at least one piezoelectric layer 5, 25.

It is advantageous when the structural layer 6 is made of a polymer. The structural layer 6 is therefore a polymeric structural layer. The polymer can be a polyamide. A polymer is softer, in particular in comparison with silicon, and therefore the piezoelectric element 4 can be made smaller, while high deflections of the piezoelectric element 4 are still possible. A performance, or power, of the piezoelectric element 4 depends inter alia on the strength of the deflection or also on the elongation. Due to the soft polymer, in particular in comparison with silicon, consistent deflections are possible in combination with smaller dimensions, in particular a shorter length, of the piezoelectric element 4.

According to the present exemplary embodiment, the at least one piezoelectric element 4 includes at least one compensation layer 7. The compensation layer 7 can compensate for tensions that arise due to the fact that the polymeric structural layer 6 tends to contract. By means of the compensation layer 7, the piezoelectric element 4 can be prevented from arching upward, or in a direction away from the carrier 2, when in an idle state due to the contraction of the polymeric structural layer 6. By means of the compensation layer 7, a neutral plane 14 (or layer) of the piezoelectric element 4 can also be adapted. The neutral plane 14 is a term from the science of the strength of materials and/or the science of tension and is also referred to as a neutral axis, or neutral line. The neutral axis, or neutral plane 14, or the neutral line, is the plane, or line, in the piezoelectric element 4 where the tensile stress and the compressive stress cancel each other out and, therefore, no tension occurs there. By comparison, either tensile stresses or compressive stresses act above and below this neutral plane 14. The tensile stress or the compressive stress naturally occurs in this case only when the piezoelectric element 4 deflects. If the piezoelectric element 4 is deflected, for example, upward, i.e., in the direction away from the carrier 2, compressive stress acts in an upper region of the piezoelectric element 4 and tensile stress acts in a lower region of the piezoelectric element 4. By comparison, when the piezoelectric element 4 deflects downward, i.e., towards the carrier 2, the compressive stress and the tensile stress are reversed. Neither tensile stress nor compressive stress act in the neutral plane 14, or in the neutral layer. This plane 14, or layer, is arranged between a top side and an underside of the piezoelectric element 4. By means of the compensation layer 7, the position of the neutral axis, or the neutral plane 14 (or layer), or the neutral line, can be adapted in terms of height, or in the direction of the stroke axis 3. By means of the compensation layer 7, in particular by means of the mechanical properties of the compensation layer 7, i.e., mechanical tension, thickness, etc., the neutral plane 14 can be shifted in the direction along the stroke axis 3. The neutral plane 14 can be shifted, or arranged, in the direction of a top side 15 of the piezoelectric element 14 or in the direction of an underside 16 of the piezoelectric element 4. The underside 16 of the piezoelectric element 4 faces the carrier 2. By comparison, the top side 15 of the piezoelectric element 4 faces away from the carrier 2.

The compensation layer 7 can be made, for example, of a metal. The metal can be, for example, gold. Additionally or alternatively, the compensation layer 7 can also be made of silicon dioxide, in particular TEOS. By means of these materials, the mechanical property of the compensation layer 7 can be easily formed.

According to the present exemplary embodiment, the MEMS sound transducer 1 includes a coupling element 9, by means of which the at least one piezoelectric element 4 can be coupled to a diaphragm 11 (shown in FIG. 1) of the MEMS sound transducer 1. By means of the coupling element 9, the deflections of the piezoelectric element 4 can be transmitted onto the diaphragm 11 when the sound waves are generated by means of the diaphragm 11. Additionally or alternatively, the deflections of the diaphragm 11 can also be transmitted onto the piezoelectric element 4 when the sound waves are detected by means of the diaphragm 11.

It is advantageous when a coupling plate 12 is arranged between the coupling element 9 and the diaphragm 11, as is shown in FIG. 1. By means of the coupling plate 12, a planar transmission of the deflections between the coupling element 9 and the diaphragm 11 can be achieved. According to the present exemplary embodiment, a diaphragm frame 13 is also shown, by means of which the diaphragm 11 can be arranged on the carrier 2.

Moreover, the at least one piezoelectric element 4 has a length 33. The length 33 is defined in this case from the carrier 2 to the free end 8 of the at least one piezoelectric element 4. The length 33 can be between 0.5 mm and 2 mm. The piezoelectric element 4 can have this length 33 due to the structural layer 6, with large deflections along the stroke axis 3 being possible. The deflection of the at least one piezoelectric element 4, in particular at the free end 8, can be at least 3%, preferably at least 100%.

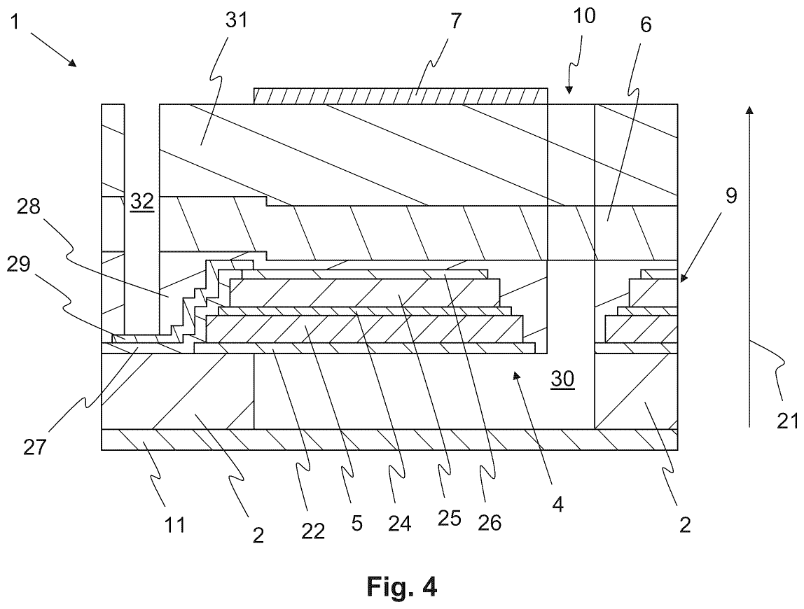

A thickness 34 of the at least one piezoelectric element 4 can be between 2 μm and 50 μm. The thickness 34 is oriented parallel to the stroke axis 3 and/or perpendicular to the layers of the at least one piezoelectric element 4 (cf. FIG. 4). A part thickness of the at least one compensation layer 7 can be between 0.5 μm and 3 μm. When multiple compensation layers 7 are present, as is shown, for example, in FIG. 4, these multiple compensation layers 7 together can have a part thickness between 0.5 μm and 3 μm.

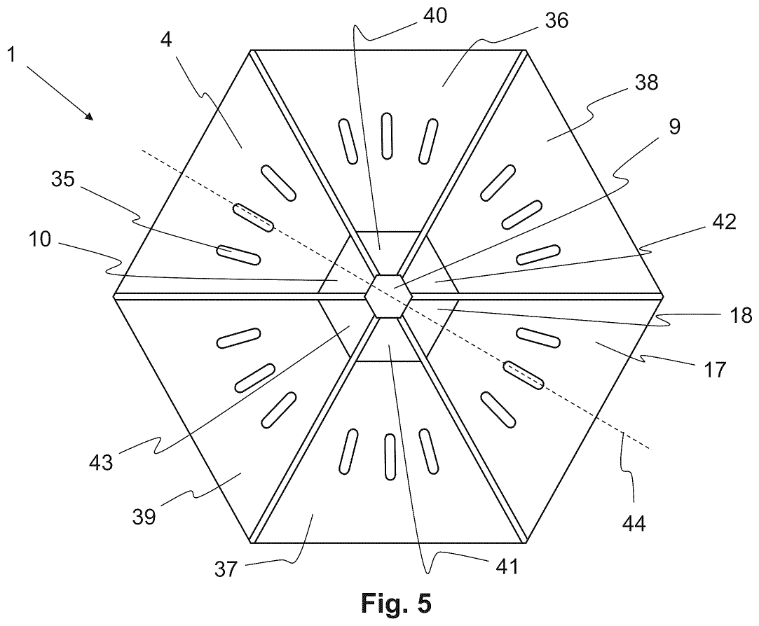

Moreover, the at least one piezoelectric element 4 can have at least one recess 35 (not shown in this figure, see FIG. 5). The at least one recess 35 can extend at least in part between the top side 15 and the underside 16. The at least one recess 35 can extend from the top side 15 and/or from the underside 16 in the direction of the respective oppositely positioned top side 15 or underside 16. By means of this recess(es) 35, tensions in the piezoelectric element 4, or in the at least one piezoelectric layer 5, in the at least one structural layer 6 and/or in the compensation layer 7 can be reduced. Additionally or alternatively, the recess 35 extends in the direction of the stroke axis 3.

Features that have already been described with reference to the at least one preceding figure are not explained once more for the sake of simplicity. Furthermore, features can also be first described in this figure or in at least one of the following figures. Moreover, identical reference characters are utilized for identical features for the sake of simplicity. In addition, all features may not be shown again in the following figures and/or provided with a reference character for the sake of clarity. Features shown in one or more of the preceding figures can also be present in this figure or in one or more of the following figures, however. Furthermore, features can also be shown and/or provided with a reference character first in this feature or in one or more of the following features for the sake of clarity. Nevertheless, features that are first shown in one or more of the following figures can also be already present in this figure or in a preceding figure.

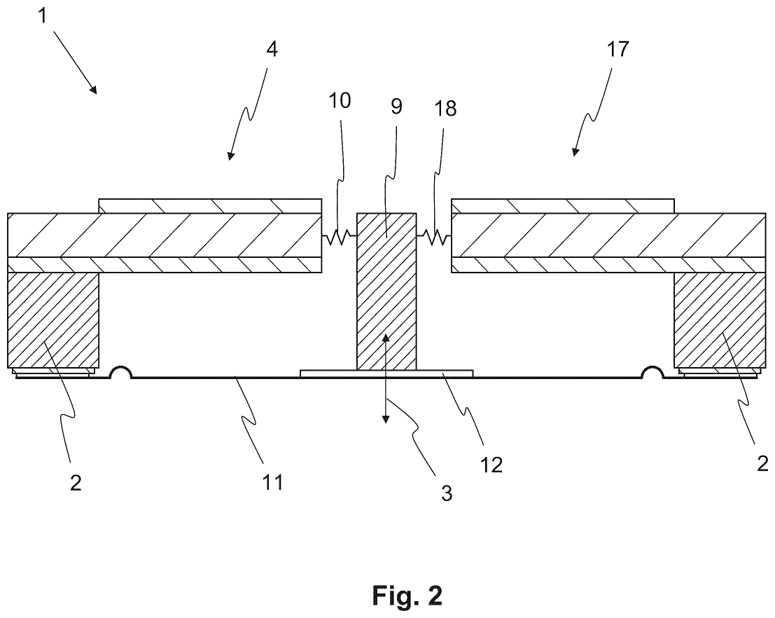

FIG. 2 shows a schematic side view of a MEMS sound transducer 1 having two piezoelectric elements 4, 17. As described above, all features are no longer described here. For example, the features of the first piezoelectric element 4 have already been described with reference to FIG. 1. Advantageously, the two piezoelectric elements 4, 17 shown here are identically designed. Consequently, the second piezoelectric element 17 therefore has the same features as the first piezoelectric element 4.

As is also apparent in FIG. 2, the two piezoelectric elements 4, 17 are coupled to the diaphragm 11 via a single coupling element 9. Moreover, the first spring element 10 is arranged between the first piezoelectric element 4 and the coupling element 9 and a second spring element 18 is arranged between the second piezoelectric element 17 and the coupling element 9. The two piezoelectric elements 4, 17 therefore both deflect the diaphragm 11 via the coupling element 9 shown in FIG. 2. Additionally or alternatively, the deflections of the diaphragm 11 can also be transmitted onto both piezoelectric elements 4, 17 via the coupling element 9.

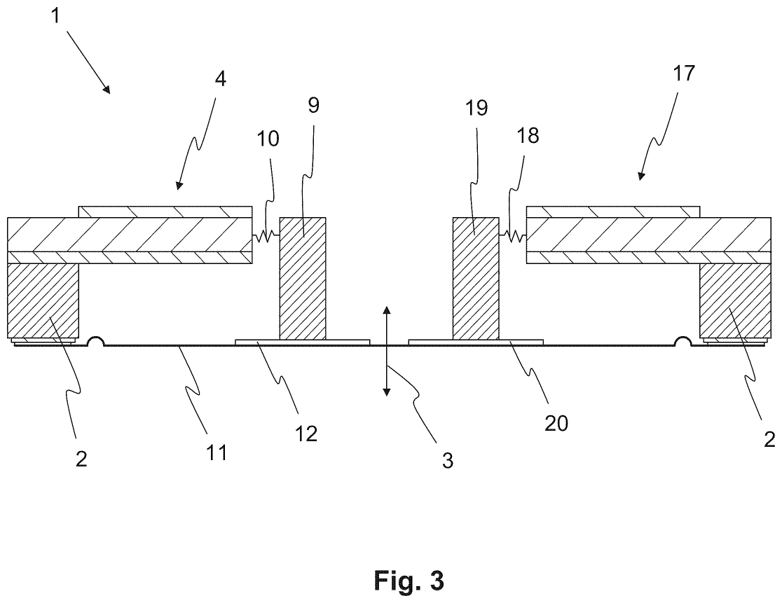

FIG. 3 shows a MEMS sound transducer 1 having two piezoelectric elements 4, 17 and two coupling elements 9, 19. The individual features that are already known from at least one of the preceding figures are also not described here once again.

As is shown in the present exemplary embodiment, the first piezoelectric element 4 is coupled to the diaphragm 11 by means of the first coupling element 9. In addition, the first spring element 10 is arranged between the first coupling element 9 and the first piezoelectric element 4. Additionally or alternatively, the first coupling plate 12 is arranged between the first coupling element 9 and the diaphragm 11.

Moreover, the second piezoelectric element 17 is coupled to the diaphragm 11 by means of a second coupling element 19. The second spring element 18 is arranged between the second piezoelectric element 17 and the second coupling element 19. A second coupling plate 20 is arranged between the second coupling element 19 and the diaphragm 11. Due to the exemplary embodiment shown here, the two piezoelectric elements 4, 17 can be coupled to the diaphragm 11 independently of one another to a certain extent.

As an alternative to the exemplary embodiment shown in FIG. 3, the two coupling elements 9, 19 shown in FIG. 3 can be coupled to the diaphragm 11 by means of a single coupling plate 12, 20. For example, the two coupling plates 12, 20 shown in FIG. 3 can be combined to form one single coupling plate 12, 20.

FIG. 4 shows a schematic lateral sectional view of a layered construction of a MEMS sound transducer 1. FIG. 4 shows the schematic design of the MEMS sound transducer 1 from FIG. 1, although without the region to the right next to the coupling element 9. This means, the right portion of the carrier 2 from FIG. 1 is not shown here in FIG. 4.

A build direction 21 is shown in FIG. 4. The layers of the MEMS sound transducer 1 shown in FIG. 4 can be built up in this build direction 21. It is also to be noted here that the layers can be arranged over the entire width of the MEMS sound transducer 1 shown in FIG. 4. This means that the regions that are not shaded in FIG. 4 are formed afterwards.

A first electrode layer 22 can be arranged, according to the build direction 21, on a carrier 2 which can extend over the entire width of the MEMS sound transducer 1 (shown in FIG. 4) at the beginning of the manufacturing process. As the manufacturing process continues, a first piezoelectric layer 5 can be formed on the first electrode layer 22. A second electrode layer 24 can be formed on the first piezoelectric layer 5. A second piezoelectric layer 25 can be formed on the second electrode layer 24. A third electrode layer 26 can be formed on the second piezoelectric layer 25. In FIG. 1, only the first piezoelectric layer 5 is shown. The piezoelectric element 4 is shown in greater detail in FIG. 4. Advantageously, the piezoelectric element 4 can include multiple piezoelectric layers 5, 25. For example, the piezoelectric element 4 can have between two and six piezoelectric layers 5, 25. In one advantageous embodiment, the piezoelectric element 4 can have four piezoelectric layers 5, 25. The electrode layers 22, 24, 26 described here are used to conduct electrical signals to the at least one piezoelectric layer 5, 25 and/or conduct electrical signals away from the at least one piezoelectric layer 5, 25.

According to the present exemplary embodiment, the coupling element 9 and the piezoelectric element 4 shown in FIG. 4 have an identical layered structure. Consequently, the coupling element 9 shown in FIG. 4 includes a portion of the carrier 2, the first electrode layer 22, the first piezoelectric layer 5, the second electrode layer 2, the second piezoelectric layer 25 and/or the third electrode layer 26. The only purpose of these aforementioned layers in the coupling element 9, however, is to build up the coupling element 9. It is advantageous with respect to the manufacturing process when the coupling element 9 and the at least one piezoelectric element 4 have an identical layered structure. As a result, the coupling element 9 and the at least one piezoelectric element 4 can be formed at the same time. In a processing step following the build-up of the coupling element 9 and of the at least one piezoelectric element 4, the two can be separated from one another, for example, by means of etching.

In addition, a first insulation layer 27 can be provided. Moreover, a contacting layer 29 can be provided in order to conduct the electrical signals to the at least one piezoelectric layer 5, 25 and/or conduct the electrical signals away from the at least one piezoelectric layer 5, 25. Furthermore, additionally or alternatively, a second insulation layer 28 can be formed. The at least one insulation layer 27, 28 is used to electrically insulate electrical conductors, for example, the contacting layer 29 and/or the at least one piezoelectric layer 5, 25.

Once these layers have been formed, for example, by means of etching, a first open area 30 can be formed. The first open area 30 is used to separate the piezoelectric element 4 shown here from the coupling element 9 and to ensure that the piezoelectric element 4 can deflect, in particular with respect to the carrier 2. Once the first open area 30 has been formed, the piezoelectric element 4 and the coupling element 9 can be coupled to each other by means of the first spring element 10.

The at least one structural layer 6, which is made of a polymer, is formed on the at least one piezoelectric layer 5, 25 and/or on the at least one electrode layer 22, 24, 26 (shown in FIG. 4). According to the present exemplary embodiment, a second structural layer 31 is arranged on the first structural layer 6. The thickness 34 of the resultant layer can be enlarged due to these multiple layers formed from the structural layers 6, 31. The at least one structural layer 6, 31 can be laminated, for example, in the form of a film, in particular a polymeric film, onto the at least one piezoelectric layer 5, 25 and/or onto the at least one electrode layer 22, 24, 26 and/or onto the at least one insulation layer 27, 28 and/or onto the at least one contacting layer 29. In this way, for example, the thickness 34 of the at least one structural layer 6, 31 can have twice the thickness of the polymeric film and the polymeric film can be laminated on twice, such that the two structural layers 6, 31 shown here are formed. The two structural layers 6, 31 can be considered as one single structural layer 6, 31, however.

Two piezoelectric layers 5, 25 are shown in this exemplary embodiment. When the piezoelectric layers 5, 25 are made of scandium aluminum nitride, it is advantageous when the at least one piezoelectric element 4, 17 has between two and six, in particular four, piezoelectric layers 5, 25.

Once the at least one structural layer 6, 31 has been formed, a second open area 32 can be formed therein. Via this second open area 32, a connection can be established to the contacting layer 29 shown in FIG. 4.

FIG. 4 also shows the first spring element 10. This first spring element 10 is formed in this case by the first and the second structural layers 6, 31.

Moreover, the compensation layer 7 is shown in FIG. 4. The compensation layer 7 extends in the longitudinal direction of the piezoelectric element 4 from the carrier 2 to the spring element 10.

The layers described with reference to FIG. 4 can be formed at least in part by means of a lithography process.

FIG. 5 shows a top view of an exemplary embodiment of the MEMS sound transducer 1. The top view is parallel to, along, or in the direction of the stroke axis 3 in this case.

A total of six piezoelectric elements 4, 17, 36-39 are shown in FIG. 5 and are arranged in an, in particular regular, polygon, specifically a hexagon in this case.

According to the present exemplary embodiment, the piezoelectric elements 4, 17, 36-39 are coupled to the coupling element 9 by means of a spring element 10, 18, 40-43, respectively. Therefore, six spring elements 10, 18, 40-43 are also shown in FIG. 5. Moreover, only one coupling element 9 is present in the illustrated embodiment of FIG. 5. Alternatively, at least one further coupling element can also be present, such that the piezoelectric elements 4, 17, 36-39 can be coupled to the diaphragm 11 by means of multiple coupling elements.

Moreover, recesses 35 are shown in FIG. 5. At least one piezoelectric element 4, 17, 36-39 can have at least one recess 35. By means of the recess 35, the mechanical property, for example, the mechanical tension and/or motion characteristics, of the piezoelectric element 4, 17, 36-39 can be adapted. The at least one recess 35 can extend in the piezoelectric layer, the structural layer and/or the compensation layer of the corresponding piezoelectric element 4, 17, 36-39.

Furthermore, a cutting plane 44 is shown in FIG. 5. For example, FIG. 2 shows the cut along the cutting plane 44. The recesses 35, for example, are not shown in FIG. 2, however.

### List of Reference Characters

1 MEMS sound transducer
2 carrier
3 stroke axis
4 first piezoelectric element
5 first piezoelectric layer
6 first structural layer
7 compensation layer
8 free end
9 first coupling element
10 first spring element
11 diaphragm
12 first coupling plate
13 diaphragm frame
14 neutral plane
15 top side
16 underside
17 second piezoelectric element
18 second spring element
19 second coupling element
20 second coupling plate
21 build direction
22 first electrode layer
24 second electrode layer
25 second piezoelectric layer
26 third electrode layer
27 first insulation layer
28 second insulation layer
29 contacting layer
30 first open area
31 second structural layer
32 second open area
33 length
34 thickness
35 recess
36 third piezoelectric element
37 fourth piezoelectric element
38 fifth piezoelectric element
39 sixth piezoelectric element
40 third spring element
41 fourth spring element
42 fifth spring element
43 sixth spring element
44 cutting plane

1-33. (canceled).

34. A MEMS sound transducer for generating and/or detecting sound waves in the audible wavelength spectrum and/or ultrasonic range, the MEMs sound transducer comprising:
a carrier; and
at least one piezoelectric element arranged on the carrier and being deflectable in the direction of a stroke axis, the at least one piezoelectric element having at least one piezoelectric layer and at least one structural layer, wherein electrical signals and deflections of the at least one piezoelectric element are convertible into each other using the at least one piezoelectric layer,
wherein the at least one piezoelectric layer is made of scandium-aluminum-nitride.

35. The MEMS sound transducer of claim 34, wherein the at least one structural layer is made of a polymer.

36. The MEMS sound transducer of claim 34, wherein the at least one piezoelectric layer is arranged between the carrier and the at least one structural layer in the direction of the stroke axis.

37. The MEMS sound transducer of claim 34, wherein the at least one piezoelectric element has a length in a longitudinal direction of the at least one piezoelectric element defined from the carrier to a free end of the at least one piezoelectric element, the length being between 0.5 mm and 2 mm.

38. The MEMS sound transducer of claim 34, wherein the at least one piezoelectric element has a compensation layer, the compensation layer being configured to equalize mechanical tensions of the at least one structural layer and/or flatten the at least one structural layer.

39. The MEMS sound transducer of claim 38, wherein the at least one structural layer is arranged between the at least one piezoelectric layer and the compensation layer.

40. The MEMS sound transducer of claim 38, wherein the compensation layer has an identical or higher mechanical tension than a mechanical tension of the at least one structural layer, wherein the mechanical tension of the compensation layer counteracts the mechanical tension of the at least one structural layer.

41. The MEMS sound transducer of claim 38, wherein a state of mechanical tension of the compensation layer counteracts, compensates for, and/or equalizes a state of mechanical tension of the at least one structural layer and/or of the at least one piezoelectric layer, the compensation layer having a state of mechanical tension between 50 MPa and 1000 MPa.

42. The MEMS sound transducer of claim 38, wherein:
the compensation layer is made of a metal and/or silicon dioxide; and/or
the compensation layer has a thickness between 0.2 μm and 4 μm.

43. The MEMS sound transducer of claim 38, wherein the compensation layer extends in a longitudinal direction of the at least one piezoelectric element to the carrier and/or to a free end of the at least one piezoelectric element.

44. The MEMS sound transducer of claim 34, wherein:
the at least one piezoelectric layer comprises multiple piezoelectric layers; and/or
the at least one piezoelectric element has at least one electrode layer; and/or
the at least one piezoelectric element has at least one insulation layer.

45. The MEMS sound transducer of claim 34, wherein the at least one piezoelectric layer comprises multiple piezoelectric layers and wherein the at least one piezoelectric element is formed from the multiple piezoelectric layers and multiple electrode layers arranged in a sandwich-like manner.

46. The MEMS sound transducer of claim 34, further comprising a coupling element and a diaphragm, the coupling element being configured to couple the at least one piezoelectric element the diaphragm.

47. The MEMS sound transducer of claim 46, wherein the at least one piezoelectric element and the coupling element are coupled to each other by at least one spring element.

48. The MEMS sound transducer of claim 47, wherein the at least one spring element is formed by the at least one structural layer and/or a polymer.

49. The MEMS sound transducer of claim 46, wherein the at least one piezoelectric element and the coupling element each have a layered construction, the layered construction for the at least one piezoelectric element being the same as the layered construction for the coupling element.

50. The MEMS sound transducer of claim 34, wherein the at least one structural layer is between 10 μm and 50 μm thick.

51. The MEMS sound transducer of claim 34, wherein the at least one piezoelectric element has at least one recess.

52. The MEMS sound transducer of claim 34, wherein:
the at least one structural layer has a modulus of elasticity between 2 GPa and 50 GPa; and/or
the at least one structural layer has a tensile strength between 70 MPa and 100 MPa; and/or
the at least one structural layer is formed such that an elongation of the at least one structural layer between 3% and 10% can be achieved.

53. A method for producing a MEMS sound transducer, the method comprising:
forming at least one piezoelectric element on a carrier such that the at least one piezoelectric element includes at least one piezoelectric layer and at least one structural layer coupled to the at least one piezoelectric layer,
wherein the at least one piezoelectric layer is made of scandium-aluminum-nitride.
